(19) United States
(12) Patent Application Publication
(10) Pub. No.: US 2006/0212773 A1
(43) Pub. Date: Sep. 21, 2006

(54) Ultrawideband architecture

(76) Inventors: Turgut Aytur, Plattsburgh, NY (US); Stephan ten Brink, Irvine, CA (US); Ravishankar H. Mahadevappa, Irvine, CA (US); Ran Yan, Holmdel, NJ (US)

Correspondence Address: CHRISTIE, PARKER & HALE, LLP, PO BOX 7068, PASADENA, CA, 91109-7068, US

(21) Appl. No.: 11/361,922

(22) Filed: Feb. 23, 2006

Related U.S. Application Data
(60) Provisional application No. 60/655,648, filed on Feb. 23, 2005.

(51) Int. Cl. H03M 13/00

(52) U.S. Cl. 714/755

(57) ABSTRACT

Architectures for ultrawideband transmitters and receivers including parallel processing chains. Some embodiments include a two byte interface with a MAC, and some embodiments include mappers mapping I-channel and Q-channel information from separate encoders.

### CROSS-REFERENCE TO RELATED APPLICATION(S)

This application claims the benefit of the filing date of U.S. Provisional Patent Application No. 60/655,648, filed Feb. 23, 2005, the disclosure of which is incorporated by reference herein.

### BACKGROUND

The present invention relates generally to wireless communication systems, and more particularly to ultrawideband orthogonal frequency division multiplexing communication systems.

Wireless communication systems, generally radio frequency (RF) communication systems, are widespread. Often such systems communicate using signals about a specific predetermined carrier frequency. Unfortunately, use of only a single carrier frequency may result in deleterious effects. Signals at specific frequencies may be particularly subject to disruption due to interference caused by multipath effects, other transmitters or other factors. Signals at specific frequencies may also dominate use of bandwidth about the specific frequencies, leaving less of the frequency spectrum available for use by others. Further signals at specific frequencies may provide insufficient bandwidth for particular communications.

Ultrawideband (UWB) communication systems generally communicate using signals over a wide band of frequencies. Use of a wide band of frequencies may allow for increased effective bandwidth between devices. Use of a wide band of frequencies also may minimize effects of interference about any particular frequency.

The use of orthogonal frequency division multiplexing (OFDM) methods by communication systems may also be beneficial for a number of reasons. Often in OFDM systems information is transmitted over a number of communication channels about different frequencies, with each channel including information transmitted over a number of sub-bands, each at slightly different frequencies.

UWB-OFDM communication systems, however, may require significant processing of transmitted and received information. Processing such information may pose difficulties, which may be compounded by the use of multiple transmit and/or receive antennas.

### BRIEF SUMMARY OF THE INVENTION

The invention provides ultrawideband transmitters and receivers, and associated methods. In one aspect the invention provides a method used in communication of data, comprising encoding a data stream; interleaving encoded symbols of the data stream; splitting the interleaved encoded symbols into a first data stream and a second data stream; and processing the first data stream and the second data stream independently.

In another aspect the invention provides a method used in communication of data, comprising receiving a data stream; separating the data stream into a first data stream and a second data stream, the first data stream including a first received orthogonal frequency division multiplexing (OFDM) symbol and every other OFDM symbol received thereafter and the second data stream including a second received OFDM symbol and every other OFDM symbol received thereafter; and separately performing processing on the first data stream and the second data stream.

In another aspect the invention provides a transmission processing system, comprising an encoder configured to provide encoded symbols; a plurality of processing chains, each of the plurality of processing chains data coupled with the encoder, each of the plurality of processing chains comprising an interleaver, a mapper coupled to the interleaver, and an inverse Fast Fourier Transform block coupled to the mapper.

In another aspect the invention provides a reception processing system, comprising a radio frequency (RF) receiver configured to receive radio frequency signals and convert the radio frequency signals to baseband signals; a plurality of processing chains, each of the plurality of processing chains data coupled with the RF receiver, each of the plurality of processing chains comprising a Fast Fourier Transform block, a demapper coupled to the Fast Fourier Transform block, and a deinterleaver coupled to the demapper.

These and other aspects of the invention are more fully comprehended upon review of this disclosure.

### BRIEF DESCRIPTION OF THE DRAWINGS

FIG. 1 is a block diagram of a transmission system in accordance with aspects of the invention;

FIG. 2 is a block diagram of a reception system in accordance with aspects of the invention;

FIG. 3 is a block diagram of a communication system in accordance with aspects of the invention, and includes a further transmission system and a further reception system, which may be used together as a transceiver;

FIG. 4 shows a 16-QAM constellation used in accordance with aspects of the invention;

FIG. 5 shows frame structures for MAC-PHY interfaces in accordance with aspects of the invention;

FIG. 6 shows a rate table in accordance with aspects of the invention;

FIG. 7 is a block diagram of a further communication system in accordance with aspects of the invention, including transmission portions and reception portions; and

FIG. 8 is a further block diagram of a further communication system in accordance with aspects of the invention, including transmission portions and reception portions.

### DETAILED DESCRIPTION

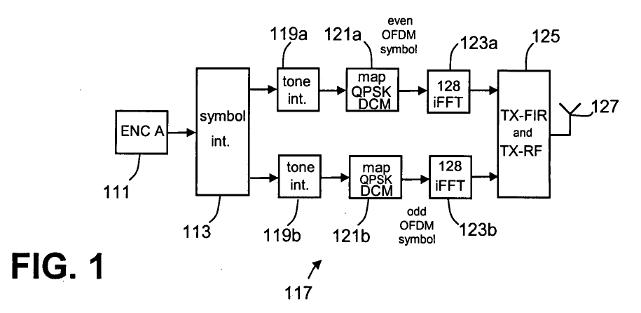

FIG. 1 is a block diagram of a transmission system in accordance with aspects of the invention. Preferably the transmission system is used for ultrawideband transmission of orthogonal frequency division multiplexing (OFDM) symbols. An encoder 111 encodes a stream of bits for error correction. Generally, the stream of bits is provided by a Media Access Controller (MAC) (not shown). In most embodiments the encoder encodes the bit stream using a convolutional code, for example with a memory of 6. Preferably the encoder encodes data at different code rates depending on selection of an information rate, generally indicated to the encoder by the MAC. In various embodiments different encoding schemes may be used. Generally, however, the encoder receives a bit stream and provides blocks of encoded symbols.

A symbol interleaver 113 receives the encoded symbols and interleaves the symbols. Interleaving of symbols is preferred so as to reduce effects of bursty errors, such as may occur during transmission over a channel of a communication medium.

Some of the interleaved symbols are provided to a first processing chain 115, and some of the interleaved symbols are provided to a second processing chain 117. The processing chains operate in parallel. Preferably, each processing chain receives every other symbol, for example the first processing chain receiving odd symbols of a sequence of symbols and the second processing chain receiving even symbols of the sequence of symbols. The use of two processing chains allows for reduction of effective clock rate used to drive the processing chains, with the use of two processing chains, for example, allowing for reduction of the clock rate by one-half of an expected clock rate for a single processing chain for processing data at similar data rates.

As illustrated, the processing chains each include a tone interleaver, a mapper 121a,b, and an inverse Fast Fourier Transform (iFFT) block 123a,b. The tone interleaver interleaves 119a,b bits of the symbols, preferably reducing possible effects of bursty errors over a particular subcarrier of a channel of a communication medium. The mapper performs a mapping of groups of bits, for example using a quadrature phase shift key (QPSK) or dual carrier modulation (DCM) (preferably corresponding to two shifted QPSK constellations over two subcarriers of a channel used for transmission of OFDM symbols) scheme. Preferably the mapper performs QPSK modulation for lower selected information rates and DCM for higher selected information rates. The iFFT transforms the mapped bits to the complex time domain.

The processing chains provide data to what is denoted in FIG. 1 as a transmission FIR-RF block 125, which radiates information using an antenna 127 FIR-RF block of FIG. 1 includes a finite impulse response (FIR) filter and upconversion mixers, amplifiers, and the like associated with RF transmitters. Preferably the FIR filter operates on four complex time samples simultaneously. In some embodiments the FIR filter is implemented as a 4× polyphase filter. An example of upconversion mixers, amplifiers, and the like associated with RF transmitters may be found in U.S. patent application Ser. No. 11/267,829, filed Nov. 3, 2005, the disclosure of which is incorporated by reference herein.

In some embodiments, in operation the encoder receives a bit stream from a MAC and encodes the bit stream using an error correction code, for example a convolutional code of memory 6. The encoder is clocked, for example, at 66 MHz. Depending on a rate selection indication provided by the MAC, the encoder encodes the bit stream using a selected code rate, for example at a ½ code rate, a ⅝ code rate, a ¾ code rate, or a ⅘ code rate.

The encoded bit stream is interleaved by a symbol interleaver and then split into two separate bit streams, each bit stream receiving bits for every other OFDM symbol. Splitting the bit stream allow further processing, such as tone interleaving, mapping, and iFFTing, to be performed at a reduced clock rate, for example at 264 MHz instead of 528 MHz.

Each of the separate bit streams are separately tone interleaved and mapped. The mapping scheme used as either a QPSK or DCM scheme, with the use of QPSK or DCM based on a rate selection signal provided by the MAC.

After mapping each signal is separately grouped into 128 subcarriers forming an OFDM symbol and transformed from the frequency domain to the time domain using, for example, a 128-point iFFT. After iFFT the signal is paralyzed by a factor of four on the time-sample level for FIR-filtering, using a clock rate of 264 MHz instead of 1056 MHz, for example, with FIR-filtering preferably being accomplished by a 4× polyphase filter.

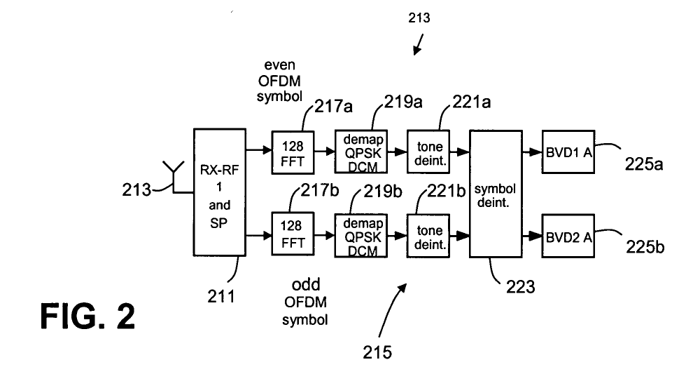

FIG. 2 is block diagram of a receiver in accordance with aspects of the invention. In what is shown in FIG. 2 as a single block, an RF receiver and signal processor block 211 receives signals via an antenna 213. The RF receiver amplifies a signal received by the antenna and downconverts the signal to baseband. The signal processor operates on the baseband signal, and for example performs packet detection, frame synchronization, and other functions normally performed by the signal processor. The signal processor of FIG. 2 also provides two symbol streams, with each stream preferably including every other symbol in the time domain. Preferably the symbol streams are also aligned in the time domain. In many embodiments separation of symbols into the parallel symbol streams occurs after an overlap-and-add unit of the signal processor removes the null prefix (which may be implemented as a null postfix).

The signal processor provides one of the two time domain symbol streams to a first processing chain 213 and the other of the two time domain symbol streams to a second processing chain 215. Use of the two processing chains, operating in parallel, allows for processing at a reduced clock rate, as compared to a clock rate required by use of only a single processing chain.

As illustrated in FIG. 2, each processing chain includes a Fast Fourier Transform (FFT) block 217a,b, a demapper 219a,b, and a tone deinterleaver 221a,b. The FFT block transforms the time domain signal to the frequency domain, the demapper recovers soft reliability bit estimates for the encoded bits of the stream, and the tone deinterleaver tone deinterleaves the bit stream. The demapper preferably demaps information using a QPSK or DCM scheme, generally as indicated by an associated MAC. In many embodiments the processing chains also include, after the FFT block, circuitry for performing channel estimation and circuitry for performing phase estimation, with the results used to compensate for multipath fading channels and phase/frequency offset. In addition, each processing chain may also include circuitry for performing frequency and/or conjugate symmetric despreading prior to demapping by the demapper.

Each of the two processing chains provides a data stream to a symbol deinterleaver 223. The symbol deinterleaver merges the two data streams and deinterleaves symbols from the data streams. The symbol deinterleaver also provides data blocks to two Viterbi decoder blocks 225a,b, preferably after depuncturing the coded bits of the symbols. It should be noted that depuncturing, as well as merging of the data streams and separating data blocks for the Viterbi decoders, may not necessarily be considered as being performed by the symbol deinterleaver, but is illustrated as such in FIG. 2 for purposes of convenience.

The Viterbi decoders decode the data, with the output of the Viterbi decoders provided to a MAC (not shown). The data provided to the Viterbi decoders has partially overlapping windows, particularly for embodiments where the data has been encoded using a single encoder. The partially overlapping windows, with data blocks for each decoder including bits in common with data blocks provided to the other encoder, are used, for example, to pre-synchronize and post-synchronize the Viterbi decoders.

In some embodiments, in operation a signal received by the antenna is amplified and downconverted to baseband. Downconversion may be performed in a frequency hopping manner, in accordance with a time-frequency pattern indicated by a MAC. The baseband signal is processed by a signal processor, performing functions such as packet detection, frame synchronization, automatic gain control determination and other functions normally performed by a baseband signal processor. Preferably the signal processor separates the time domain sample stream into two streams, with each stream containing every other OFDM symbol. In such implementations the signal processor may largely, or entirely, incorporate parallel processing streams, with data received from analog-to-digital conversion circuitry split into two streams operated on separately by the signal processor, with every other OFDM processed by each parallel processing stream. In many embodiments, however, parallelization is accomplished after packet detection and after removal of a null prefix (which may be a postfix) in the time domain.

The parallel streams are each provided to a separate processing chain, including, for example, a 128-point FFT block, a demapper, and a tone deinterleaver. Each processing chain separately transforms their respective signals from the time domain to the frequency domain, demaps the OFDM symbols to obtain soft bit estimates, and deinterleaves using the tone deinterleaver. Each processing chain is for example clocked at 264 MHz, assuming an ADC of the receiver is clocked at 528 MHz. The bits provided by the separate processing chains, each providing every other OFDM symbol, are merged and deinterleaved by a symbol deinterleaver. Preferably the deinterleaved bits are decoded by parallel Viterbi decoders.

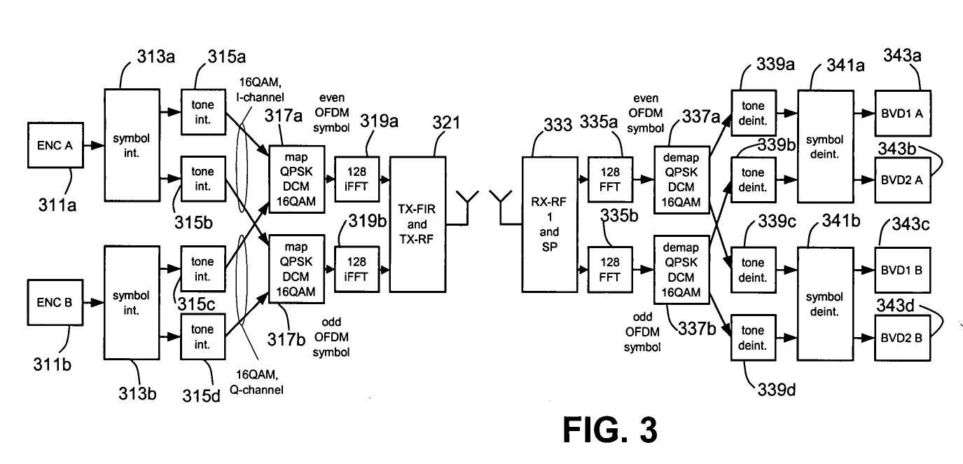

FIG. 3 is a block diagram of a further transmitter and a further receiver in accordance with aspects of the invention. The transmitter and the receiver of FIG. 3 have similarities to the transmitter of FIG. 1 and the receiver of FIG. 2, respectively. For example, the transmitter includes a symbol interleaver generating parallel data streams, tone interleavers working on the separate data streams, mappers mapping working on (at least a portion) of the separate data streams, and iFFT blocks transforming (at least a portion) of the separate data streams. Similarly, the signal processor of the receiver provides parallel data streams, each operated on by separate FFT blocks and separate mappers, and (at least partially) separate tone deinterleavers.

The transmitter of FIG. 3, however, includes two encoders 311a,b, each of which operate on different data. The data is provided, for example, by a MAC (not shown). Preferably the MAC provides data in the form of words instead of bytes, and a first encoder operates on a low byte of the word and a second encoder operates on a high byte of the word. Each of the encoders provide encoded data to a symbol interleaver 313a,b, which operates as discussed with respect to the transmitter of FIG. 1. As with the symbol interleaver of FIG. 1, each symbol interleaver provides parallel data streams to two separate tone interleavers 315a-d, with the parallel data streams containing even and odd OFDM symbols, respectively. The tone interleavers also operate as discussed with respect to the transmitter of FIG. 1, each tone interleaver providing a separate data stream.

The transmitter of FIG. 3 also includes two mappers 317a,b. The mappers map tone interleaved data according to a mapping scheme. Preferably each mapper receives some data from a tone interleaver associated with the first encoder and some data from a tone interleaver associated with the second encoder, with for example mapper 317a receiving data from tone interleaver 315a and tone interleaver 315c. In one embodiment the mappers map data using a 16 quadrature amplitude modulation (QAM) constellation, and each mapper uses data from a tone interleaver associated with the first encoder for I-channel mapping and data from a tone interleaver associated with the second encoder for Q-channel mapping. Preferably the mappers maps data using either a QPSK modulation scheme, a DCM scheme, or the 16QAM constellation, with the selected scheme based on an information rate selected by the MAC.

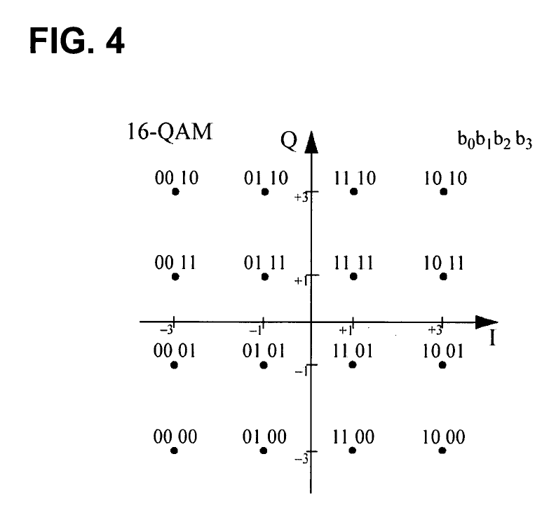

Referring to the QAM constellation of FIG. 4, a 16-QAM constellation is shown. The 16-QAM constellation includes 16 points, each point representing a different location in the I-Q plane, and corresponding for example to different magnitudes and phase offsets. Each point maps four bits, for example bits b0,b1,b2,b3. Bits b0 and b1 determine position in the I dimension and bits b2 and b3 determine position in the Q dimension. Preferably, bits b0 and b1 are provided by a tone interleaver associated with the first encoder and bits b2 and b3 are provided by a tone interleaver associated with the second encoder (or vice versa).

Returning to FIG. 3, each mapper provides symbols to separate iFFT blocks 319a,b, which operate on the symbols as discussed with respect to the transmitter of FIG. 1 and provides time domain data to a FIR filter/RF block 321 for transmission via an antenna 323.

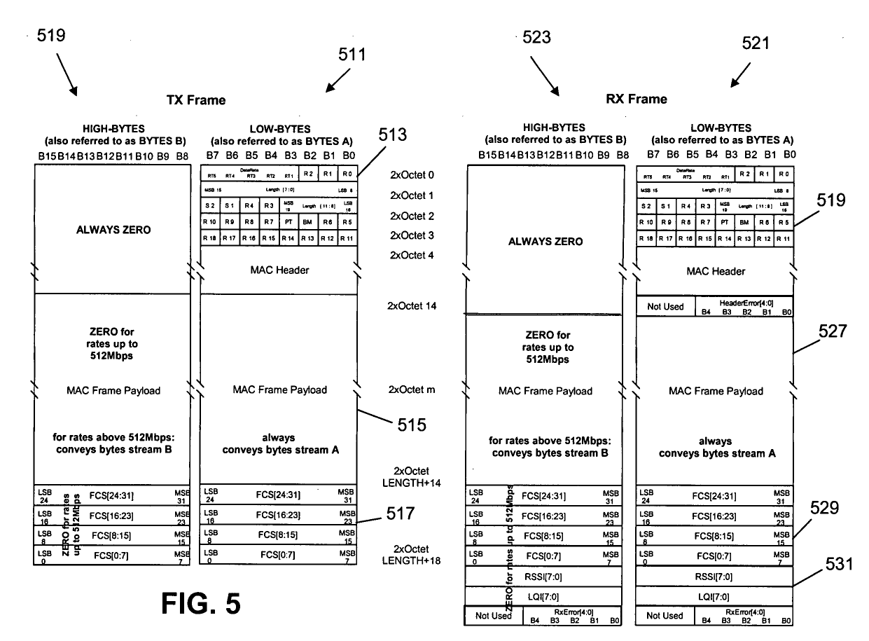

FIG. 5 shows an example transmission frame structure for data received from a MAC and an example frame structure for data provided to a MAC. The MAC provides data to the first encoder in accordance with a first frame structure 511. The first frame structure includes a MAC header 513, a MAC frame payload 515, and Frame Check Sequence (FCS) bits 517. In addition, in some embodiments bit R3 of the MAC header further provides length information. The MAC provides data to the second encoder in accordance with a second frame structure 519. Preferably the second encoder only receives data when higher data rate transmission is desired. The second frame structure is, in layout, similar to the first frame structure. In the second frame structure, however, data in the MAC header is zero. In some embodiments a single four byte FCS is calculated for both the first and second frame structures, for example with the second frame structure including bits 16:23 and 0:7 and the first frame structure including bits 24:31 and 8:15.

Returning again to FIG. 3, the receiver of FIG. 3 has similarities to the receiver of FIG. 2. For example, the receiver receives signals using an antenna 331, and includes signal reception circuitry and a signal processor 333 as in FIG. 2. Also as in FIG. 2, the signal processor provides parallel data streams, which are separately transformed to the frequency domain by separate FFT blocks 335a,b. The output of each FFT block is also received by a separate corresponding demapper 337a,b.

Each demapper demaps data, for example in accordance with the 16-QAM constellation of FIG. 4. In the receiver of FIG. 4, in contrast to the receiver of FIG. 2, a portion of each demapper output is provided to a tone interleaver 339a,b associated with a first symbol deinterleaver 341a and a portion of each demapper output is provided to a tone interleaver 339a,b associated with a second symbol deinterleaver 341b. Preferably, I-channel bits from each demapper are provided to tone deinterleavers associated with the first symbol deinterleaver and Q-channel bits from each demapper are provided to tone deinterleavers associated with the second symbol deinterleaver.

Each of the first symbol deinterleaver and the second symbol deinterleaver are associated with two Viterbi decoders 343a-d. Operation of each group of symbol deinterleaver and two Viterbi decoders operate as discussed with respect to the symbol deinterleaver and two Viterbi decoders of the receiver of FIG. 3.

Preferably, however, the output provided to a MAC (not shown) is provided in accordance with the receive frame structure of FIG. 5, which includes a third frame structure 521 and a fourth frame structure 523 (the first and second frame structures being described with respect to the transmission frame structure). The third frame structure includes a MAC header 525, a MAC frame payload 527, FCS bits 529, and bits for a Received Signal Strength Indicator (RSSI) and Receiver Error 531. Output of the Viterbi decoders associated with the first symbol deinterleaver provides data for the MAC frame payload of the third frame. The fourth frame structure is similar to the third frame structure, except that the MAC header is zero. Data for the MAC frame payload of the fourth frame structure is provided by the Viterbi decoders associated with the second symbol deinterleaver.

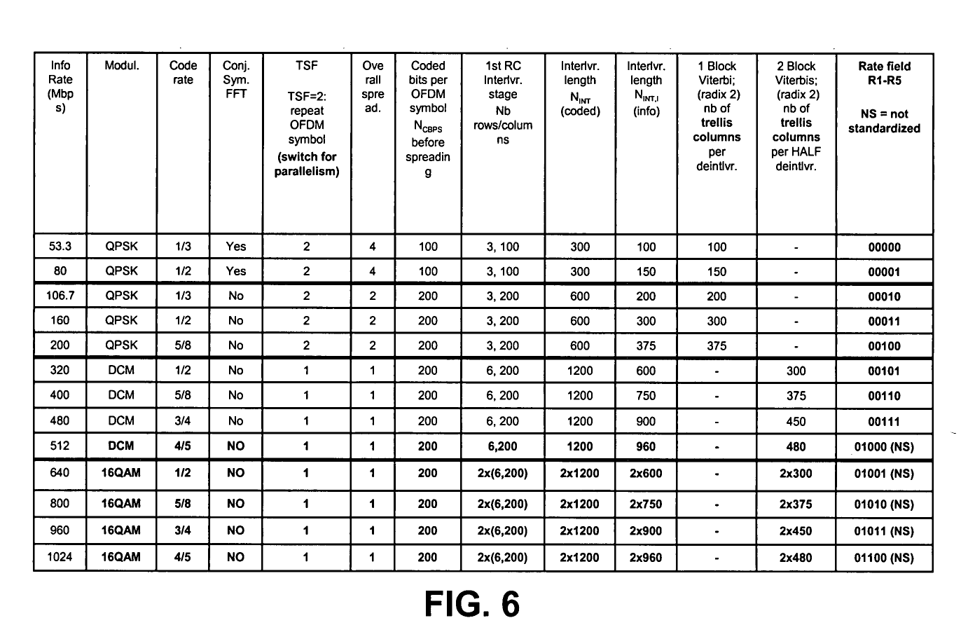

In some embodiments the system of FIG. 3 supports communication at data rates between 53.3 Mbps and 1024 Mbps. FIG. 6 shows a rate table for communication at discrete information rates between 53.3 Mbps and 1024 Mbps. Different modulation (mapping) is implemented by the mappers/demappers and different codes rates are implemented by the encoders/decoders, for example, based on a selected information rate.

In operation of some embodiments, data is received from and provided to a MAC over a two byte interface and the number of encoding/decoding and interleaving/deinterleaving elements are doubled. Accordingly, in some embodiments a high byte is encoded by a first encoder and low byte is encoded by a second encoder. A symbol interleaver, and dual tone interleavers, are associated with each encoder. Two mappers each separately map interleaved encoded bits associated with both encoders. Interleaved encoded bits associated with the first encoder are mapped to onto the I-channel of a 16 QAM constellation, and interleaved encoded bits associated with the second encoder are mapped onto the Q-channel of the 16 QAM constellation. Processing thereafter on the transmission side is performed as discussed with respect to operation of embodiments of FIG. 1. Processing on the receive side is as discussed with respect to FIG. 2, until demapping and thereafter, which is the dual of that described above.

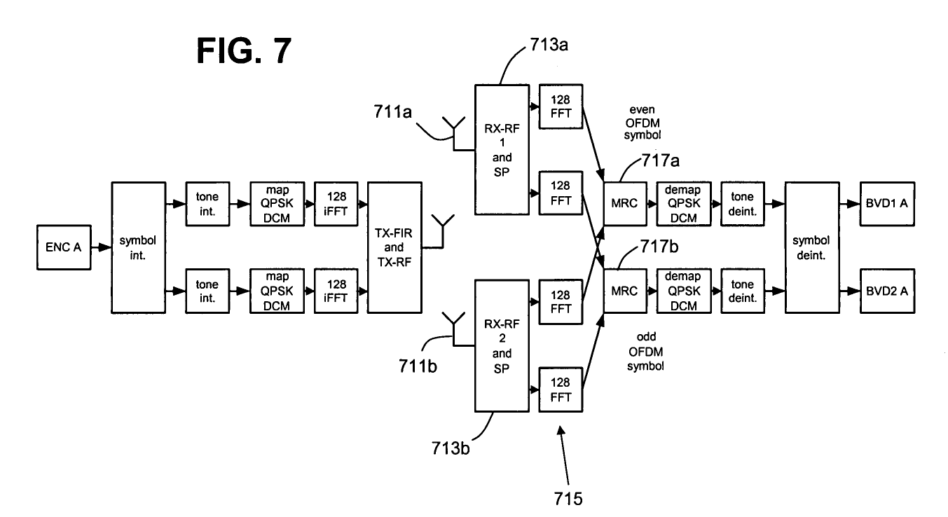

In some embodiments the receiver includes multiple receive antennas. For example, FIG. 7 is a block diagram of a receiver similar to the receiver of FIG. 2. The receiver of FIG. 7, however, includes multiple receive antennas 711a,b, with two receive antennas illustrated. Each receive antenna is associated with and provides signals to a corresponding receiver circuitry and signal processor 713a,b. The signal processor for each antenna performs, for example, packet detection, frame synchronization, and, in various embodiments, processing associated with control of automatic gain control features of the receiver. The signal processor for each antenna also provides parallel data streams, preferably as described with respect to the receiver of FIG. 2. The data streams of each parallel data stream is received by an FFT block of a plurality of FFT blocks 715, with a first FFT block associated with a particular signal processor providing even OFDM symbols and a second FFT block associated with the particular signal processor providing odd OFDM symbols for example.

Outputs of the FFT blocks are received by parallel maximum ratio combining (MRC) blocks 717a,b. For convenience indicating the outputs of the FFT blocks as either even or odd symbols, outputs of FFT blocks providing even symbols are received by a first MRC block 717a and outputs of FFT blocks providing odd symbols are received by a second MRC block 717b. Accordingly, each MRC block receives representations of the same signal as received by the different antennas. Each MRC block performs a diversity combining function, preferably summing the signals, and doing so weighting each of the signals to be summed by their respective signal-to-noise ratios.

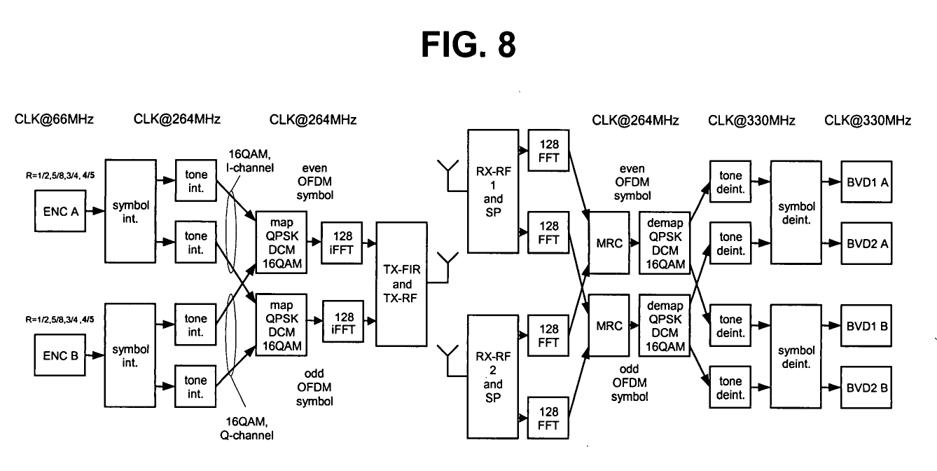

FIG. 8 also shows a block diagram of a further receiver using multiple receive antennas. Other than the use of multiple receive antennas and related processing, as discussed with respect to the receiver of FIG. 7, the receiver of FIG. 8 is similar to the receiver of FIG. 3. In addition, in some embodiments, both with respect to FIG. 8 and FIGS. 1, 3, and 7, transmission is performed with multiple antennas, and preferably associated up-conversion circuitry, such as two antennas preferably in a cross-polarized configuration each possibly with associated up-conversion circuitry.

Accordingly, the invention provides ultrawideband transceiver and transceiver component architectures. Although the invention has been described with respect to certain specific embodiments, it should be recognized that the invention comprises the novel and non-obvious claims supported by this disclosure and insubstantial variations thereof.

1. A method used in communication of data, comprising:
encoding a data stream;
interleaving encoded symbols of the data stream;
splitting the interleaved encoded symbols into a first data stream and a second data stream; and
processing the first data stream and the second data stream independently.

2. The method of claim 1 wherein encoding the data stream comprises convolutional encoding the data stream.

3. The method of claim 1 wherein the first data stream comprises every other symbol of the data stream and the second data stream comprises symbols of the data stream not part of the first data stream.

4. The method of claim 1 wherein processing the first data stream and the second data stream independently comprises at least one of separately tone interleaving the first data stream and tone interleaving the second data stream; separately mapping the first data stream and the second data stream, separately performing an inverse fast fourier transform (iFFT) on the first data stream and the second data stream.

5. The method of claim 4 wherein processing of symbols of the first data stream and the second data stream occurs simultaneously.

6. A method used in communication of data, comprising:
receiving a data stream;
separating the data stream into a first data stream and a second data stream, the first data stream including a first received orthogonal frequency division multiplexing (OFDM) symbol and every other OFDM symbol received thereafter and the second data stream including a second received OFDM symbol and every other OFDM symbol received thereafter;
and separately performing processing on the first data stream and the second data stream.

7. The method of claim 6 wherein the processing includes fast fourier transform (FFT) processing, demapping, and tone deinterleaving.

8. The method of claim 7 further comprising merging the first data stream and the second data stream for symbol deinterleaving.

9. The method of claim 8 further comprising decoding the deinterleaved symbols using multiple Viterbi decoders.

10. The method of claim 9 wherein decoding the deinterleaved symbols using multiple Viterbi decoders comprises providing each Viterbi decoder different blocks of deinterleaved symbols, with at least a partial overlap of symbols between at least some of the different blocks.

11. A transmission processing system, comprising:
an encoder configured to provide encoded symbols;
a plurality of processing chains, each of the plurality of processing chains data coupled with the encoder, each of the plurality of processing chains comprising an interleaver, a mapper coupled to the interleaver, and an inverse Fast Fourier Transform block coupled to the mapper.

12. The transmission processing system of claim 11 wherein the interleaver comprises a tone interleaver, and further comprising a symbol interleaver coupled to receive symbols from the encoder and to provide symbols to the plurality of processing chains.

13. The transmission processing system of claim 12 wherein the symbol interleaver is configured to provide different interleaved symbols to different processing chains.

14. The transmission processing system of claim 13 wherein the symbol interleaver is configured to provide different interleaved symbols to different processing chains in a time interleaved manner.

15. The transmission processing system of claim 14 further comprising a transmitter coupled to the processing chains, the transmitter configured to transmit data processed by the processing chains.

16. The transmission processing system of claim 15 wherein the mapper is configured to modulate data in accordance with a modulation scheme.

17. The transmission processing system of claim 16 wherein the modulation scheme is at least one of a QPSK scheme, a DCM scheme, and a mapping scheme.

18. The transmission processing system of claim 11, further comprising a further encoder and a further plurality of interleavers data coupled to the further encoder, wherein a first of the further plurality of interleavers provides data operated on by a mapper of a first processing chain and a second tone interleaver provides data operated on by a mapper of a second processing chain.

19. The transmission processing system of claim 18, wherein the mapper of the first processing chain uses data from an interleaver of the first processing chain and the first of the further plurality of interleavers and the mapper of the second processing chain uses data from an interleaver of the second processing chain and the second of the further plurality of interleavers.

20. The transmission processing system of claim 19 wherein the interleaver of the first processing chain and the interleaver of the second processing chain provide data for one of the I-channel or Q-channel, and the first and second of the further plurality of interleavers provide data for the other of the I-channel or Q-channel.

21. A reception processing system, comprising:
a radio frequency (RF) receiver configured to receive radio frequency signals and convert the radio frequency signals to baseband signals;
a plurality of processing chains, each of the plurality of processing chains data coupled with the RF receiver, each of the plurality of processing chains comprising a Fast Fourier Transform block, a demapper coupled to the Fast Fourier Transform block, and a deinterleaver coupled to the demapper.

22. The reception processing system of claim 21 wherein the deinterleaver comprises a tone deinterleaver, and further comprising a symbol deinterleaver coupled to receive symbols from the tone deinterleavers of the plurality of processing chains and to provide symbol information to at least one decoder.

23. The reception processing system of claim 22 wherein the symbol deinterleaver is configured to provide symbol information to a plurality of Viterbi decoders.

24. The reception processing system of claim 23 wherein the symbol deinterleaver is configured to provide symbol information with overlapping windows to each of the Viterbi decoders.

25. The reception processing system of claim 21 wherein a signal processor associated with the RF receiver is configured to process the baseband signals and configured to provide different signals to different processing chains.

26. The reception processing system of claim 25 wherein the signal processor is configured to provide different signals to different processing chains in a time interleaved manner.

27. The reception processing system of claim 21, further comprising a further decoder and a further plurality of deinterleavers data coupled to the further decoder, wherein a first of the further plurality of deinterleavers receives data operated on by a demapper of a first processing chain and a second of the further plurality of deinterleavers receives data operated on by a demapper of a second processing chain.
